(19) United States
(12) Patent Application Publication
(10) Pub. No.: US 2024/0279826 A1
(43) Pub. Date: Aug. 22, 2024

(54) SYSTEM FOR THE CIRCULAR PRODUCTION OF HYDROGEN AND OXYGEN WITH FEEDBACK FROM RESIDUES OF THERMAL ENERGIES, RECOVERED IN THE STIRLING ENGINE STAGE AND IN THE ELECTROLYSIS STAGE

(71) Applicant: Carlos Alberto Hernandez Abarca, Santiago (CL)

(72) Inventor: Carlos Alberto Hernandez Abarca, Santiago (CL)

(21) Appl. No.: 18/568,925

(22) PCT Filed: Sep. 13, 2021
(86) PCT No.: PCT/CL2021/050084

§ 371 Date: Dec. 11, 2023

(51) Int. Cl. C25B 9/67; C25B 1/04; F02B 65/00; H10N 10/10

(52) U.S. Cl. CPC C25B 9/67; C25B 1/04; F02B 65/00; H10N 10/10

(57) ABSTRACT

A system for the circular production of hydrogen and oxygen with feedback of residual thermal energy, recovered in the Stirling engine stage and in the electrolysis stage, to increase the efficiency of the process of subsystems that transform the conversion of heat into electrical energy to operate a hydrogen electrolyzer.

In many production processes, there are losses of energy, which can be classified into Thermal Energy (associated with high and low temperatures), Chemical Energy (associated with municipal waste or fuels) or Mechanical Energy (associated with high pressure and movement).

Although there are multiple techniques for recovering these losses (Waste Energy Recovery) and in particular for the loss in Thermal Energy that is present in Metal Foundries and Furnaces, this invention provides a scalable Heat Recovery system with heat recovery units (conversion of heat into electrical energy) that provides electric energy to power a hydrogen electrolyzer.

This system is a solution with little interference in the infrastructure of a productive process, and it allows energy to be stored and transferred in the form of liquid hydrogen.

Historically, traditional solutions consider conducting the hot gases to a point of concentration, point at which heat is converted into electricity using traditional techniques, such as for example, the transferring of the heat to water, the steam obtained from this transfer is used as a motive force for a turbine. It is also known that the transport of hot gases in production processes increases in complexity depending on the composition of said gases, often with a high corrosive power as they also increase their complexity given the pressure associated with the gases. On the other hand, the insertion of devices into the gas transport pipes implies different levels of complexity, depending on the corrosive power of the gases and the generation of incrustations at the insertion point, in some cases of crystallizations and in others metallic incrustations.

The use of hydrogen technologies implies a change in how the energy is used, as it presents better efficiencies and a drastic reduction in greenhouse gas emissions. This is why it is best to integrate it with renewable energy sources, or with discarded energy sources.

One of the important properties of hydrogen is the specific energy of its combustion. Its value is 120 MJ/kg in comparison with 50 MJ/kg of natural gas, or with 44.6 MJ/kg of oil. This contrasts with the low density it presents both as a gas and a liquid, to the storage and transport difficulties.

However, its ability to be stored makes it appropriate as a complement to some renewable energies that work intermittently or are irregular such as wind or solar energies.

This work is different from that of invention patents H1053904562 and H8,726,661. The first one refers to a system for the recovery and conversion of Thermal Energy produced in the pyrometallurgical process plants into electrical energy. Made up of at least one heat transfer chamber, which at the same time consists of an interface section for the gases, so as to make the subsystem independent of the corrosive power and the generation of incrustations of the gases from the heat source or duct. Heat energy is converted into mechanical energy by means of a Stirling-type engine; said mechanical energy obtained by said Stirling engine is converted into electrical energy by the use of a mechanical-electrical converter.

While invention patent H8,726,661 uses an after-treatment system of exhaust gases to treat an exhaust gas feed stream of an internal combustion engine that includes a catalytic converter, a fluidic circuit and a Stirling engine. The Stirling engine transforms thermal energy from a working fluid heat exchanger into mechanical energy that can be transferred to an electrical motor/generator to generate electrical power. The Stirling engine is configured to transform the mechanical energy of the electrical motor/generator into thermal energy transferable to the working fluid heat exchanger.

As mentioned, in the present invention a system is elaborated, which in addition to generating electrical energy by extracting energy from pyrometallurgical processes, it is stored as hydrogen, while at the same time oxygen is obtained as a by-product. Likewise, this system, unlike those previously presented, includes a process of heat recovery, by means of feedback subsystems based on thermoelectric modules. So, the system as a whole has a different purpose and methodology for generating energy.

With regard to the use of solar thermal energy for the production of hydrogen, we can cite the patent CN110093618, in which there is a device for the production of hydrogen from water by distributed photothermal electrolysis and a hydrogen fuel cell system, which is characterized by including a dish-type Stirling machine, a water pump, an electrolysis cell, a hydrogen separator, hydrogen storage, hydrogen fuel cell, a DC (Direct Current)/unidirectional DC converter, a bidirectional DC/DC converter, battery and DC/AC (Alternating Current) inverter.

Helium or hydrogen is used as a working gas in the Stirling engine. The hydrogen separator is used to separate hydrogen and water vapor, as part of the mixed gas does not participate in the reaction of water vapor electrolysis, the separation is suitable for the purification and storage of hydrogen, which is carried out in a high-pressure tank, between 70 MPa and 140 MPa.

The working method of the hydrogen production device from water distributed photothermal electrolysis and a hydrogen fuel cell system is as follows: the pump injects water into the dish-type Stirling machine, the working gas is heated by gathering sunlight. Heat exchange heats water into steam at high temperature and generates electrical energy at the same time; it introduces steam at high temperature into the cathode of the electrolyte cell, and uses a small amount of battery energy or residual energy from the system for electrolysis, obtaining a mixed gas, which is separated and purified by means of a hydrogen separator. The hydrogen is stored, while the water vapor is returned to the disc of the Stirling machine for recycling; hydrogen is transported from the storage to the anode of the hydrogen fuel cell, and the chemical energy from hydrogen fuel is converted into electrical energy through an electrochemical reaction. Part of the electrical energy produced by the hydrogen fuel cell reaches the end of the load through the unidirectional DC/DC converter and the DC/AC inverter, and the other part inputs to the battery through the bidirectional DC/DC converter.

However, unlike in the present invention, no thermoelectric modules are used, nor is there any mention of devices oriented to energy feedback to increase the efficiency of the system. On the other hand, the system of the aforementioned patent takes advantage of solar energy and is therefore not applicable to solve the problem of the use of waste energy from pyrometallurgical sources.

Another patent that produces hydrogen from heat energy is the SN209976669, which refers to a system to improve the efficiency of an internal combustion engine, to generate hydrogen from the energy of the exhaust gases of a vehicle. The invention drives a Stirling generator to act using the heat generated by combustion. The Stirling generator provides electrical energy for the electrolysis of water. In addition, it has a rectifier to rectify the electric current output from the Stirling generator, to generate direct current voltage that feeds a water electrolysis bath to form electrolysis products, hydrogen and oxygen. The system also comprises a capacitor that is used to reuse internal combustion engine products, to complement the water consumed by the reaction of electrolysis.

Again, there is no mention of feedback subsystems based on thermoelectric devices or similar. On the other hand, dealing with exhaust gases from internal combustion engines, does not solve the problem of harnessing the heat generated in gases from pyrometallurgical processes, which presents other challenges such as working with higher gas temperatures and flows, and with compounds that are more corrosive.

Also, patents U.S. Pat. No. 9,040,012B2, ES0315385 and H20100258449 can be mentioned that show systems for the production of hydrogen, however, these only comprise what would be the electrolyzer phase of the invention, so they do not solve the said problems. It should be noted that the U.S. Pat. No. 9,040,012B2 and H20100258449 documents may incorporate a supply of energy from renewable sources, but these correspond to solar and tidal sources, respectively. This reaffirms the fact that it does not respond to the same field and problem as the present invention.

In addition, patents H20080041054 and SN106188199 account for hydrogen production systems powered by Stirling engine cycles or similar sources, but like those mentioned in the preceding paragraph, these use solar sources instead of emissions of metallurgical processes and do not have energy feedback stages such as those indicated in this invention.

In addition to the above-mentioned documents of the state of the art, there is the ES2742623 patent, which refers to a power production plant to satisfy the energy needs of an industry, understood as any process or activity demanding energy. In addition, the plants can generate power exclusively for sale, with no associated industry. This plant is characterized for having three differentiating traits:
1. Use of renewable energy sources, process without greenhouse gas emissions, or thermal pollution.
2. Capacity for energy storage and management through the production of hydrogen by electrolysis. Achieving energy densities not achieved by technologies based solely on conventional batteries.
3. The use of synergies to increase the production of electrical energy and additionally produce thermal energy and other products that can be used in the industry.

The plant has a power generating block based on photovoltaic solar energy that can be supported by wind energy, the power production ceded by this block is increased due to residual heat recovery systems, which take advantage of thermal energy sources at a certain temperature to produce electric power by means of Stirling engines and additionally can produce useful heat at a lower temperature than that of the input temperature to be harnessed in another process. These residual heat recovery systems can be fed with heat produced in the plants themselves or in the industry that the plants supply energy to, and the useful heat produced in these systems can be used in the industry that produces synergies. The plant has a hydrogen-based energy storage system that allows for efficient energy management due to higher storage capacities than systems based solely on conventional batteries.

According to the state of the art of the industry, it is evident that, although the utilization of thermoelectric modules for energy recovery is known in several fields of the art, it has not been used in the field of hydrogen production systems or processes as proposed in this patent. The feedback of energy to increase its efficiency is a characteristic element of the invention and for this we include a device designed for the adaptation of voltage levels, transforming to alternating voltage and synchronizing with the voltages and currents energizing the described system.

### BRIEF DESCRIPTION OF THE FIGURES

To better understand this invention, a system for the circular production of hydrogen and oxygen with feedback from residual thermal energy, recovered in the Stirling engine stage and in the electrolysis stage, we will describe it on the basis of the schematic figures of this invention, without restricting it to obvious similarities that might arise.

FIG. 1 shows a schematic summary of the system's general representation. It shows each of the subsystems, and each of the stages of electricity generation, hydrogen production, heat capture and adaptation. The feedback stages are set in green, which seek to increase the efficiency of the system, by reusing the residual heat from the different stages of the process.

FIG. 2 shows a schematic representation of the feedback subsystems based on thermoelectric modules. It is possible to observe the disposition of the appropriating element (a) which receives the heat energy (d) and delivers it to the thermoelectric device (b), producing electrical energy (e). It has a heat sink element (c) that improves the efficiency of the assembly. The diagram is valid for both feedback stages since only the heat sources change, and both surface heat from the machines and their fluids can be used by means of suitable heat exchangers.

### DESCRIPTION OF THE INVENTION

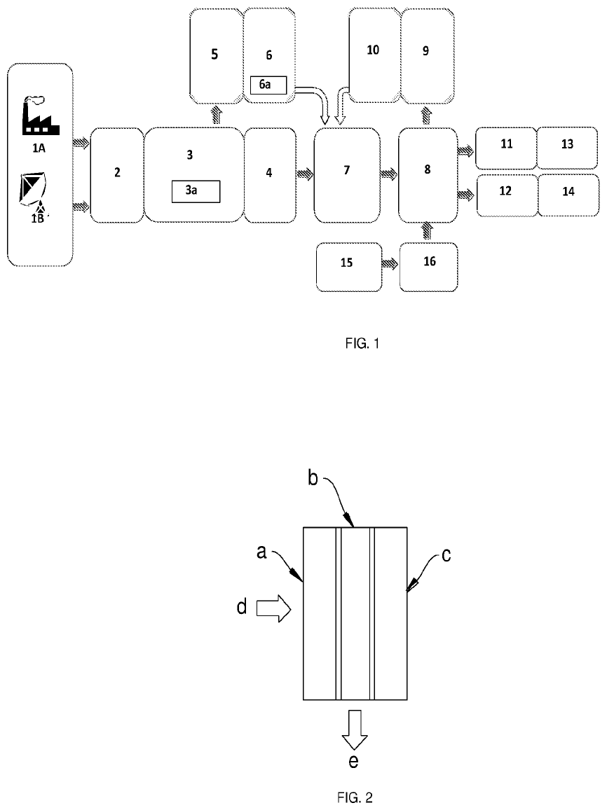

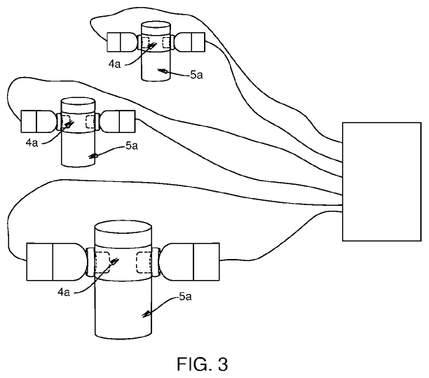

In view of FIGS. 1 and 2, the invention directly addresses the problems of energy efficiency by means of a “process and system for the circular production of hydrogen and oxygen with feedback from residual thermal energies.”

More specifically, the invention consists of a system comprised of subsystems that transform residual heat energy into electrical energy to operate a hydrogen electrolyzer, such as from a pyrometallurgical process (Casting). In addition, the process has two stages of heat feedback, a) a system that takes advantage of the heat emanating from the primary energy conversion, either by direct contact or by heat exchanger with refrigerant fluid and b) using the heat emanating from a hydrogen electrolyzer. For stages a) and b) the conversion into electrical energy is carried out by means of thermoelectric cells or similar where the following basic elements are considered:

The primary heat supply (1), either by pyrometallurgical process (1A), auxiliary plants where residual heat exists, or solar thermal equipment (1B), or similar; a primary heat adaptation medium or element (2), consisting of extended surfaces of materials resistant to abrasion or heat stress, depending on the type of heat supply, which allows residual heat to be stored and captured and transmitted, then a converter from primary heat to mechanical energy (3), by means of a Stirling engine (3a); a primary generator for the conversion of mechanical to electrical energy (4); a secondary heat feedback system (5), consisting of an adaptation element for the heat lost in the primary conversion stage and a secondary residual heat converter (s), which consists of an interface of a heat promoter, for example, thermal paste or the like, and/or an extended surface on which is mounted an element capable of converting the heat lost by the Stirling engine (3a) into electrical energy by means of a TEG (6a) device (thermoelectric module) or similar; concentrator and adjuster of electrical energy levels, by means of a voltage regulator, which collects the electrical energy generated by the primary converter (3) or Stirling engine (3a) and by the feedback suppliers (concentrator and adaptor of electrical power) (7); which are connected to a hydrogen electrolyzer (8), provided with a tertiary feedback system (10), consisting of the residual heat adaptor (equivalent to the secondary converter (8)) and the tertiary adaptation of residual heat (9) and the tertiary converter based on thermoelectric or similar modules (10), which uses the residual heat from the said hydrogen electrolyzer (8) which is connected to a subsystem, which is made up of pressurized H2 (11) and an O2 pressurizer (12), a H2 dispenser (13), and an O2 (14) heatsink; it also presents a supply of water (15), for the hydrogen electrolyzer (8); and a system of adaptors and filters, preferably purification equipment via osmosis or industrial filters or similar (18) for the feed water (15).

In this way, one or more generation subsystems are installed at different points of the production process, that is, in a distributed way, generating hydrogen with different energy sources leaving it available for distribution to different processes, plants, or machines.

The system for the recuperation and conversion of thermal energy produced in the pyrometallurgical process plants, consists of at least one primary heat converter (3) to mechanical energy, which in turn is composed of a heat adaptation section of extended surfaces, resistant to abrasion and thermal stress, embedded in the pyrometallurgical process duct or a heat transfer chamber (2) or similar, it is connected to a Stirling engine (3a) or similar and a primary electric generator (4), said heat adaptation system (2) has characteristics specific to the environment from which the heat will be extracted, being the metals resistant to corrosion and temperature of the environment, thus avoiding the generation of incrustations due to heat source gases, which negatively impact heat transfer. This heat adaptor (2) corresponds to a support ring (4a) (as per FIG. 3) or similar, which allows the heat adaptor subsystem to be mechanically connected to the pipe (5a) (according to FIG. 3) of the pyrometallurgical process.

The electrical energy produced in the primary generator (4) is adapted in a separator system in the electrical power adaptor (7), which receives the electricity generated by the feedback stages (6) and (10). The system electrically feeds the hydrogen electrolyzer (8).

There are two feedback systems, the first of which focuses on adapting and converting the residual heat energy of the primary converter (3), either from the surface of the machinery or from the heat captured by the fluids of the refrigeration systems of these units. The second feedback system is dedicated to adapting and transforming the heat dissipated by the hydrogen electrolyzer (8). In both cases (primary and secondary converter) thermoelectric devices (TEG) (6a) or similar are used for the production of electricity, as shown in FIG. 2.

The hydrogen production system also has a set of subsystems, the main one being the hydrogen electrolyzer (8) where hydrolysis is carried out. As water without hardness or contamination is needed, there is a stage of filtration (16) and adaptation of the water supply (15). Finally, you have a pressurized system to store hydrogen (11) and oxygen (12) generated in the electrolyzer in a smaller volume. In addition, it has a hydrogen (13) and oxygen (14) dispensing system for subsequent use.

The following are the elements of the system for a pyrometallurgical process:
1.—Primary heat adaptation (2), composed in turn of two sections:
a) Interface to gases consisting of extended surfaces to promote the flow of thermal energy, with material characteristics and adequate physical design, so as to make the subsystem independent of the corrosive power and the generating of incrustations of the gases from the heat source (1A).
b) Linking section with the Stirling engine.
2.—Stirling Engine (3a):

A thermal engine, which, by means of a cyclic compression and expansion of a fluid gaseous operating system, at different temperature levels, produces a net conversion of thermal energy to mechanical energy.
3.—Mechanical-Electrical Converter or Generator (4), which transforms mechanical energy into electrical energy, which, by means of a properly insulated and channeled cable, transports the electrical energy to a concentrator (7) for the distribution to the hydrogen electrolyzer (8). In addition, in this same generator (4) is carried out the adjustment of voltage levels, the transformation to alternating voltage and the synchronization with the equipment voltages and currents.
4. Hydrogen generating system, composed of three main sections:
(a) Hydrogen-oxygen electrolyzer (8), a system capable of separating hydrogen and oxygen by the electrolysis of water.
(b) Pressurizers (11) and (12), in which hydrogen and oxygen are liquefied to be stored in smaller volumes.
c) A filter (16), where, by means of different separation techniques, impurities are removed from the water supply.
5.—Secondary feedback, a system consisting of a residual heat capture and adaptation stage (5), either by an interphase of supports and/or pipes connected to the cooling systems of the Stirling engine constituting a heat exchanger, and a thermoelectric converter (6) consisting of Peltier modules or similar.
6.—Tertiary feedback, which has a heat capture and adaptation stage (9), either by an interphase of supports and/or pipes connected to the exhaust systems of the hydrogen and oxygen electrolyzer (8) constituting a heat exchanger, and a thermoelectric converter as described in the previous point.

1.—System for the circular production of hydrogen and oxygen with feedback from residual thermal energy, recovered in the Stirling engine stage and in the electrolysis stage, to increase the efficiency of the process of subsystems that transform the conversion of heat into electrical energy to operate a hydrogen electrolyzer, for the supply of primary heat (1), either by the pyrometallurgical process (1A), auxiliary plants where there is residual heat, or thermal solar equipment (18), CHARACTERIZED by the fact that it is made up of a medium or element of primary heat adaptation (2), a primary heat to mechanical energy converter (3), by means of a Stirling engine (3a) which is connected to a primary mechanical to electrical energy conversion generator (4); also to a secondary residual heat feedback system (5), consisting of an adaptation element of the heat lost in the primary heat conversion stage (3) and to a secondary residual heat converter (6), which consists of an interface of a heat promoter, for example, thermal paste or similar, and/or an extended surface on which is mounted an element capable of converting the heat lost by the Stirling engine (3a) into electrical energy by means of a thermoelectric module device (6a); a concentrator and adjuster of levels of electrical energy, by means of a voltage regulator, which collects the electrical energy generated by the primary converter (3) or Stirling engine (3a) and by feedback feeders (7) (concentrator and adaptor of electrical energy); which are connected to a hydrogen electrolyzer (8), provided with a tertiary feedback system (10), consisting of the residual heat adaptor (equivalent to the secondary converter (6)) and the adaptation of a tertiary residual heat (9) and a tertiary heat converter (10), based on thermoelectric modules (6a), which uses the residual heat from said hydrogen electrolyzer (8); which connects to a subsystem, which liquefies hydrogen and oxygen to be stored in smaller volumes, which is made up of pressurized H2 (11) and an O2 pressurizer (12), an H2 dispenser (13), and an O2 dissipator (14); there is also a supply of water (15), to the hydrogen electrolyzer (8) with a system of adaptation and filters (18), preferably being purification equipment through osmosis or industrial filters or similar.

2.—System for the circular production of hydrogen and oxygen with feedback from residual thermal energy, according to claim 1, CHARACTERIZED by the fact that the primary heat adaptor element (2), consists of extended surfaces made of materials resistant to abrasion or heat stress, depending on the type of heat supply, which allows residual heat to be maintained, captured, and transmitted.

3.—System for the circular production of hydrogen and oxygen with feedback from residual thermal energy, according to claim 1, CHARACTERIZED by the fact that the system for the recovery and conversion of thermal energy, produced in pyrometallurgical process plants, consists of at least one converter from primary heat (3) to mechanical energy, which in turn is composed of a section of adaptation of heat of extended surfaces, resistant to abrasion and heat stress, embedded in the pyrometallurgical process duct or a heat transfer and fitting chamber (2) or similar, a Stirling engine (3a) or similar and a primary electrical generator (4), said system of and transfer (2) is comprised of a support ring (4a) which allows it to be kept connected mechanically to the heat adaptation subsystem (2) with pipes (5a) of the pyrometallurgical process.

4.—System for the circular production of hydrogen and oxygen with feedback of residual thermal energy according to claim 1, CHARACTERIZED by the fact that the electrical energy produced in the primary generator (4) is adapted into a separator system in the adaptor of electrical energy (7), which also receives the electricity generated by the feedback (6) and (10), the system electrically feeds the hydrogen electrolyzer (8).

5.—System for the circular production of hydrogen and oxygen with feedback from residual thermal energy, according to claim 1, CHARACTERIZED by the fact that one or more generating subsystems are installed at different points in the production process, for example, in a distributed manner, generating hydrogen with different sources of heat energy, leaving it available for distribution to the different processes, plants, or machines.

6.—System for the circular production of hydrogen and oxygen with feedback of residual thermal energy, recovered in the Stirling engine stage and in the electrolysis stage, according to claim 1, CHARACTERIZED by the fact that such feedback systems, the first dedicated to adapt and convert the residual thermal energy of the primary converter (3), either from the surface of the machinery or from the heat captured by the fluids of the refrigeration systems of these units; the second feedback system is dedicated to adapt and transform the heat dissipated by the hydrogen electrolyzer (8). In both cases (primary and secondary converter) thermoelectric devices (6a) (TEG) or similar are used for the production of electricity.
